(19) United States
(12) Patent Application Publication
(10) Pub. No.: US 2020/0068757 A1
(43) Pub. Date: Feb. 27, 2020

(54) ROBOT END EFFECTOR FOR MEMORY MODULE AND PROCESSOR INSTALLATION

(71) Applicant: Hewlett Packard Enterprise Development LP, Houston, TX (US)

(72) Inventors: Jonathon Hughes, Houston, TX (US); David W. Deis, Spring, TX (US)

(21) Appl. No.: 16/111,161

(22) Filed: Aug. 23, 2018

(51) Int. Cl. H05K 13/04; B25J 15/08; H05K 13/08

(52) U.S. Cl. CPC H05K 13/0411; B25J 15/08; H05K 13/0882; H05K 13/0812; H05K 13/0813; H05K 13/0413

(57) ABSTRACT

An example robot end effector includes a memory module gripper that to selectively grip a memory module, and a CPU gripper that is to selectively grip a processor and/or a heatsink. The CPU gripper is attached to the memory module gripper such that they are movable relative to the one another between a first configuration and a second configuration.

### BACKGROUND

A computing system (such as a server, storage array, converged system, composable system, etc.) may include a printed circuit assembly (“PCA”) (aka printed circuit board assembly, or PCBA) comprising a printed circuit board (“PCB”) to which computing components (such as processors, memory, etc.) are attached. The PCA and/or the PCB may occasionally be referred to as a main board or motherboard. In some manufacturing approaches, the PCB and the computing components are manufactured separately, and are later assembled together to form the completed PCA by installing the components in corresponding sockets or connectors in the PCB. For example, the PCB, may include a processor socket, in which a processor may be installed, and memory module sockets, in which memory modules may be installed.

### BRIEF DESCRIPTION OF THE DRAWINGS

FIG. 1 illustrates a perspective view of an example robot end effector in a first configuration in which an example CPU gripper is positioned to be used.

FIG. 2 illustrates a perspective view of the example robot end effector of FIG. 1 in a second configuration in which an example memory module gripper is positioned to be used.

FIG. 3 illustrates a plan view of the example robot end effector of FIG. 1, facing the example memory module gripper.

FIGS. 4A and B illustrate the example memory module gripper with pincers in a closed and open orientations, respectively.

FIG. 5 illustrates a perspective view of a portions of the example memory module gripper.

FIG. 6 illustrates a perspective view of an example robotic system.

FIG. 7 illustrates a plan view of an example workstation of the example robotic system of claim 6.

FIG. 8 illustrates a control and plumbing diagram of the example robotic system of claim 6.

FIG. 9 illustrates an example method.

### DETAILED DESCRIPTION

### 1. Introduction

Processors and memory modules are generally delicate and susceptible to damage during handling, especially during manual installation in a PCB. For example, split connectors on memory modules, bent processor socket pins, and broken processor substrates are all common types of damage that can occur during manual installation, usually because of misalignment of the component and the socket on the PCB and/or excessive force being applied while seating the component in the socket. Because processors and memory modules are fairly expensive, such damage during installation can result in substantial costs.

One approach to reduce the likelihood of such damage during installation is to replace manual human installation of processors and memory modules in PCBs with a robotic installation process. However, robotic installation raises its own challenges, particular in the cost and complexity of a robotic system that is capable of installing processors and memory modules.

Accordingly, disclosed herein are technologies for robotic installation of processors (and/or heatsinks) and memory modules that can reduce the incidence of component damage while also avoiding some of the cost and complexity that may be associated with other approaches to robotic installation. In particular, disclosed herein are novel robot end effectors, example systems that utilize the end effectors to install processors and memory modules, and example methods of using such robot end effectors and systems.

Specifically, an example robot end effector disclosed herein includes a memory module gripper (to grip memory modules) and a CPU gripper (to grip a processor and/or a heatsink), with the two grippers being fixed together part of the same end effector. The memory module gripper and the CPU gripper may be attached to one another so as to allow them to move relative to one another (e.g., rotate) between a first configuration in which one of the grippers is positioned to be used and a second configuration in which the other one of the grippers is positioned to be used. For example, in the first configuration both grippers may be pointing in the same direction with the one that is to be used being extended lower than the other, while in the second configuration the grippers may be pointing in different directions. For example, in the first configuration the memory module gripper and CPU gripper may both be pointing vertically downward relative to the robot arm (e.g. towards a horizontal workbench below the robot arm), and in the second configuration the CPU gripper may be rotated to point horizontally while the memory module gripper continues to point downward.

In examples disclosed herein, the CPU gripper may include a vacuum suction cup that is to selectively grip a processor and/or heatsink by suction. The memory module gripper may include, for example, a frame, a pneumatic piston connected to the frame, pincers rotatably connected to the frame, and a mechanical linkage that converts between translational movement of the piston and rotation of the pincers. The pincers may be configured to grip opposing edges of a memory module when closed and to release the memory module when opened.

In some examples, the CPU and/or the memory module grippers may have some built in tolerance for variations in socket heights while seating their payloads in the PCB. In particular, the CPU and/or the memory module grippers may apply force against their payloads to seat them in the PCB, and have built in compliancy that prevents the applied force from becoming excessive when the component resists further movement. Specifically, in this context, having compliancy means that the portion of the gripper that is pushing against the component is configured to elastically yield in response to resistance from the component, such as by elastically deforming or compressing (in the case of a gas). That is, if the component resists moving in the installation direction (for example, because it has already reached the bottom of the socket), the end effector does not rigidly and unyieldingly push on the component. Instead, the compliancy of the end effector results in a modest force being applied to the component that is sufficiently low to not cause damage to the component or the PCB if the component resists moving.

For example, the compliancy in the memory module gripper may be provided by the compression of air in the pneumatic piston in response to the mechanical linkage being pressed upward by a memory module that is being seated. Because the air in the pneumatic piston can be compressed without excessive force (for small displacements of the piston), the force that is applied to the memory module when it resists movement is relatively modest.

In some examples, the compliancy in the CPU gripper may be provided by the deformation of the vacuum suction cup. For example, the vacuum suction cup may be formed from an elastically deformable material (e.g., an elastomer such as rubber) that provides a modest elastic restoring force against the processor or heatsink that is being seated.

### 2. Example Advantages and Benefits

As noted above, the example end-effectors, systems, and method disclosed herein may be used to install components such as processors, heatsinks, and memory modules in a PCB. Such robotic installation of the components greatly reduces the likelihood of a processor or memory module being damaged during installation as compared to manual installation. Thus, examples disclosed herein may be able to greatly reducing the costs associated with assembly of the PCA.

Not only do the technologies disclosed herein provide benefits relative to manual installation of components, the disclosed technologies also may have certain advantages or benefits when compared to other possible approaches to robotic installation of components in a PCB. Some of these advantages are described below.

Because the grippers disclosed herein are part of the same single end effector, a single robot may be used to install both processors and memory modules without having to switch out end effectors between installing different components. In some circumstances, this may be advantageous when compared to alternative approaches in which multiple robots are used to install CPU's and memory modules, or in which multiple end effectors are provided and switched out between installing different types of components.

For example, if multiple robots are used (e.g., one with a memory module gripper and another with a CPU gripper), then this increases the cost of the robotic system as compared to examples disclosed herein in which one robot may be used (each robot is usually very expensive).

As another example, if multiple end-effectors are used (e.g., a CPU end effector for installing CPUs and a memory module end effector for installing memory modules), then one of the end effectors needs to be removed and the other one attached between installing the different parts. However, this may result in a slower, more complex, and more expensive installation process as compared to the example technologies disclosed herein. In particular, detaching one end effector and attaching another end effector adds additional steps to the installation process and takes more time and increases complexity of the process, especially if the change in end effectors is done manually by a human technician. Moreover, if the change in end effectors is to be done automatically by the robot, then this may require a more complex, and thus more expensive, robotic system that is capable of such automatic end effector changes.

In addition, in example end effectors disclosed herein, not only are the CPU gripper and memory module gripper part of the same single end effector, but they are also both configured to grip their respective payloads from a same direction relative to the arm of the robot. In other words, the CPU gripper and the memory module gripper both point in the same direction, relative to the arm of the robot, when they are picking up their respective payload. This is beneficial because it enables a less complex robotic system to be used. In particular, the example end effectors disclosed herein may be usable with a four-axis robot and a simple workbench setup, while other approaches may require a six-axis robot and/or a complex work bench setup.

A four-axis robot may include an arm that can be moved translationally in three-dimensions and also rotated about the arm's axis. With such a four-axis robot, the arm may always be pointed in the same direction (e.g., downward) regardless of where the arm is moved. Thus the four-axis robot is generally only able to grasp payloads that are located so as to be grasped from the direction in which the arm points. For example, if the arm points vertically downward, then the robot is generally only able to grasp payloads that are arranged so as to be grasped from above, such as objects arranged on a horizontal workbench. In the examples disclosed herein, this constraint is not a problem because the CPU gripper and memory module gripper are configured to pick up their respective payloads from a same direction relative to the arm. For example, in examples disclosed herein, if the arm of the robot points vertically downward, then the CPU gripper and the memory module gripper also both point vertically downward (when picking up their payload), and thus both are able to grasp their respective payloads arranged on a simple horizontal workbench.

In contrast, in an alternative approach a memory module gripper and a CPU gripper may be included in the same end effector, but unlike the examples disclosed herein, in the alternative approach the gripers are arranged to point in different directions (for example, one points vertically downward and one points horizontally to the side). Because the grippers point in different directions in this alternative approach, either a six-axis robot would be needed to enable both grippers to be usable or a complex workbench setup would be needed to enable a four-axis robot to be used. A six-axis robot would enable both grippers of the end effector of the alternative approach to be used because a six-axis robot can change the direction in which the arm points, and thus either one of the grippers could be pointed in the needed direction to grasp their payload by manipulating the robot arm's orientation. However, such a six-axis robot is much more expensive and is more complex to operate than a four-axis robot. Furthermore, in order to use a four-axis robot instead of a six-axis robot, a specialized workbench may be needed that is capable of holding one payload in such a way that it can be grasped from one direction (e.g., from above) while also holding another payload in such a way that it can be grasped from a different direction (e.g., from the side). For example, one payload tray may need to be horizontal while the other payload tray is vertical. However, such a setup can be complicated to construct, and may be more difficult to operate than a simple horizontal workbench. For example, it may be more difficult to load new payload trays onto the workbench since the vertical tray may need special procedures to secure it in place. As another example, payload in the vertical tray may be harder to secure and keep from falling out (thus requiring either special equipment, or introducing another source of possible error). Thus, one benefit of the examples disclosed herein may be that they enable a four-axis robot to be used rather than requiring a six-axis robot, and they do so without requiring such complex specialized workbench arrangements.

In addition, in example end effectors disclosed herein, the CPU gripper and the memory module gripper are configured to be moveable relative to one another. For example, the CPU and memory module grippers may rotate relative to one another. This may enable both grippers to have a same gripping direction (i.e., the direction they point when they are being used to grip their payload), but may allow one of the grippers to be moved out of the way (e.g., pointing horizontally) when it is not being used. This may be beneficial because otherwise a gripper that is not being used would be likely to collide with the work desk, objects on the work desk, and/or parts of the PCB when the other gripper is being used. For example, if the memory module gripper is being used to install memory modules and if both grippers permanently point in the same direction (e.g., downward), then the CPU gripper may collide with other memory modules in a memory module tray while the memory module gripper is attempting to grasp one of the memory modules from the tray. By enabling, for example, the CPU gripper to rotate out of the way when it is not being used, the memory module gripper can grasp the memory modules from the tray without the CPU gripper bumping into things.

In addition, as noted above, in example end effectors disclosed herein, the memory module gripper and/or the CPU gripper are configured to have built-in compliancy when installing the CPU and/or memory modules. This compliancy is greatly beneficial because it allows the robotic system to tolerate the sockets in the PCB being at slightly different heights than expected without causing damage. In particular, unless extraordinary measures are taken to avoid it, the sockets of the PCB are not always going to be at the desired height—for example, the sockets may have slightly different heights due to variations in their manufacture (e.g., different solder thicknesses, etc.), or a technician may have seated the PCB imperfectly on the workbench, etc. When a socket is higher than expected, the component being seated in it will cease moving into it sooner than expected (when it hits the bottom of the socket). The robot, unaware that the component has been fully seated, continues to force the end effector downward towards the location that would correspond to the expected height for the socket. Thus, if there is no compliancy, the continued downward movement of the end effector coupled with the resistance to movement of the component may result in a spike of excessive force being applied to the component and the PCB, which may damage the component and/or the PCB. In contrast, when the end-effector has compliancy, the component is allowed to resist the end effector with only modest forces being applied to it, thus avoiding the damage.

In addition, in examples disclosed herein, the compliancy may be provided by the structure of the grippers themselves. This may provide an additional benefit in that expensive and complicated force/pressure detectors or feedback sensors, which might otherwise be required to enable toleration of varying socket heights, may be omitted.

### 3. Example Robot End Effector

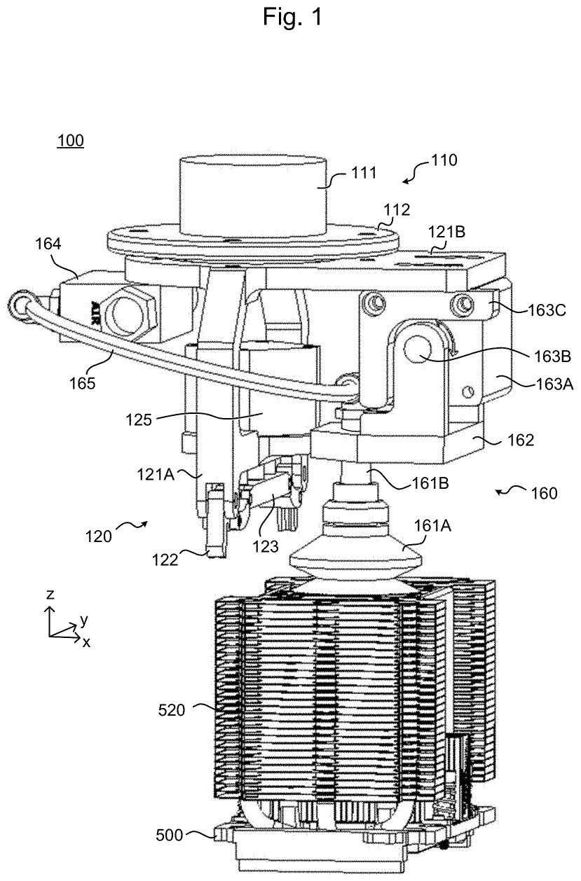

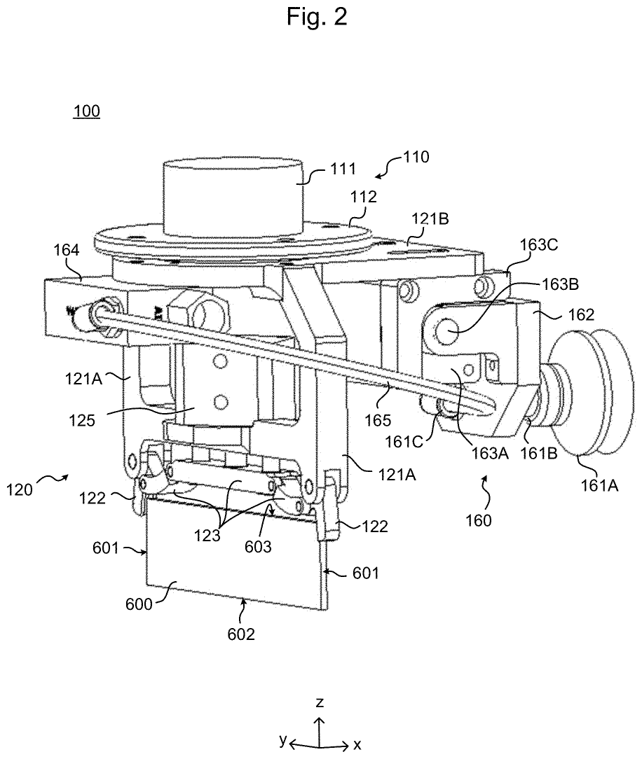

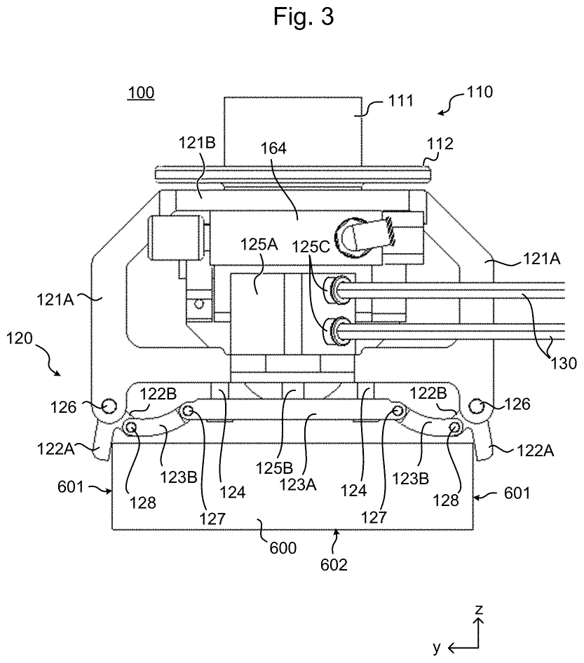

FIGS. 1 and 2 illustrate an example robot end effector 100 (also referred to as “end effector 100”). FIGS. 3-5 illustrate additional details of the example robot end effector 100, particularly details of a memory module gripper 120. As used herein, a “robot end effector” or “end effector” is the device attached at the very end of a robot's arm that is designed to interact with its environment, such as a gripper or tool. In some examples, an end effector is permanently attached to an arm of the robot, but in other examples the end effector may be removably attachable to the arm (enabling a generic robot to be configured for a specialized task by attaching the appropriate end effector).

The end effector 100 includes a memory module gripper 120 and a CPU gripper 160. The memory module gripper 120 is configured to grip memory modules (such as the memory module 600). The CPU gripper 160 is configured to grip a processor 500 and/or a heatsink 520. In some implementations, the processors 500 and heatsinks 520 may be connected together as a single assembly prior to being installed in the PCB 400 (such as in the example of FIG. 1), in which case the CPU gripper 160 can grip the assembly by gripping a top of the heatsink 520. In some implementations, the processors 500 and heatsinks 520 may be installed separately. In some implementations, the CPU gripper 160 is able to grip both a processor 500 and its corresponding heatsink 520, but does so one at a time. In some implementations the CPU gripper 160 may be able to grip one of the processor 500 and its corresponding heatsink 520 but is not able to grip the other. In some examples, the CPU gripper 160 may also be able to grip other objects.

As described above, the end effector 100 may be configured such that the memory module gripper 120 and the CPU gripper 160 are moveable relative to one another. Specifically, they may be moveable relative to one another between at least two configurations, with one configuration being used when the memory module gripper 120 is to pick up a memory module 600 and the other configuration being used when the CPU gripper 160 is to pick up a processor 500 and/or heatsink 520. The configurations may be such that the one of the grippers 120 or 160 that is not being used is out of the way and does not interfere with the one of the grippers 120 or 160 that is being used or with the workstation.

For example, as illustrated in FIGS. 1 and 2, the grippers 120 and 160 may be rotated relative to one another between two configurations, where they are pointing in the same direction in one configuration and in different directions in the other configuration. Specifically, in FIG. 1, the end effector 100 is shown in a first configuration in which the CPU gripper 160 and the memory module gripper 120 are pointed (oriented) in the same direction, namely the −z direction in the figure. In FIG. 2, the end effector 100 is shown in a second configuration in which the CPU gripper 160 and the memory module gripper 120 are pointed (oriented) in different directions, namely in the −z direction for the memory module gripper and the +x direction for the CPU gripper 160. As used herein, a gripper being “pointed” in a given direction means that the orientation of the gripper is such that a location at which a payload would need to be disposed in order to be gripped by the gripper is aligned with the gripper along the given direction. So, for example, if it is said that the memory module gripper 120 is “pointed” downward (−z), as in FIGS. 1 and 2, then this means that the memory module gripper 120 is oriented such that a memory module 600 would need to be directly below the gripper 120 (i.e., aligned with the gripper in the downward direction) in order to be gripped.

As another example (not illustrated), the grippers 120 and 160 may always point in the same direction, but one of the grippers 120 or 160 may be moved translationally up or down between two configurations. For example, the CPU gripper 160 could move down to extend lower than the memory module gripper 120 when the CPU gripper 160 is to be used, and the CPU gripper 160 could move upward when the memory module gripper 120 is to be used such that the memory module gripper 120 extends lower than the CPU gripper.

The various components of the end effector 100 will be described in greater detail in sections 3.1 through 3.4 below.

3.1 The CPU Gripper 160

The CPU gripper 160 will now be described in greater detail with reference to FIGS. 1 and 2.

The CPU gripper 160 includes a suction cup device 161 connected to and supported by a frame 162. The frame 162 is connected to and supported by a rotating support 163. The rotating support 163 enables the CPU gripper 160 to rotate relative to the memory module gripper 120 and/or relative to the arm of the robot. For example, in the implementation of FIGS. 1 and 2, the rotating support 163 is connected to the upper portion 121B of the frame 121 of the memory module gripper 120 and to the frame 162, such that the frame 162 can rotate relative to the frame 121. The rotating support 163 will be described in greater detail in section 3.4.

The suction cup device 161 is to grip a processor and/or a heatsink by suction adhesion. The suction cup device 161 may include a suction cup portion 161A and a columnar portion 161B. The columnar portion 161B may be connected to the frame 162, and may support the suction cup portion 161A. The columnar portion 161B and the suction cup portion 161A may have hollow interior volumes that are communicably connected to one another. The columnar portion 161B may be connected to a vacuum line 165 such that an interior volume of the vacuum line 165 is communicably connected with the interior volumes of the columnar portion 161B and suction cup portions 161A. Thus, air can be pumped out of the interior volumes of the columnar portion 161B and the suction cup portion 161A via the vacuum line 165.

The suction cup portion 161A may be made from an elastomer such as a rubber, which enables it to deform elastically. The suction cup portion 161A may be configured to form a suction seal on a flat surface of an object disposed below it when the suction cup portion 161A is pressed against the surface and the pressure within the suction cup device 161 is lowered. The suction cup portion 161A may also include a bellows-like expansion joint to enhance a compliancy of the suction cup device 161 by enabling greater elastic deformation of the section cup portion 161A.

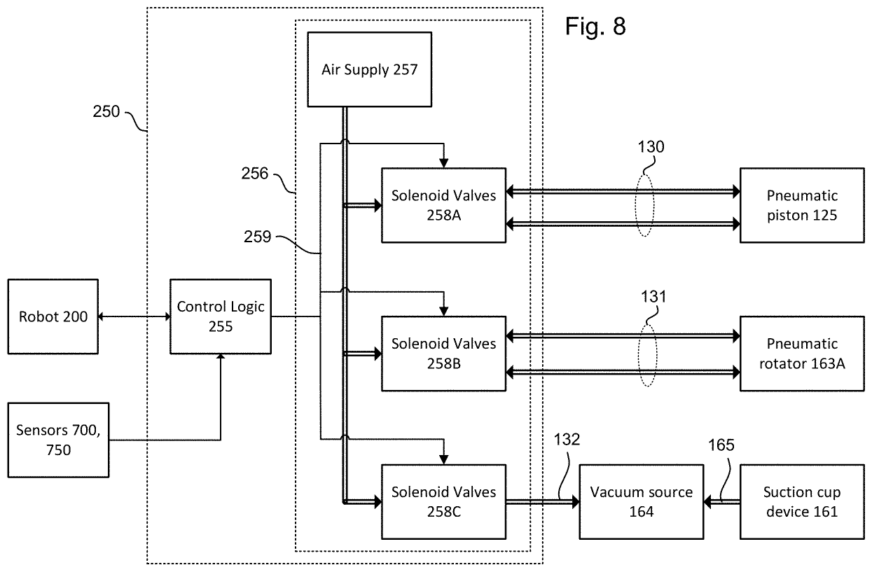

As noted above, air may be evacuated from the interior of the suction cup device 161 via the vacuum line 165, and if this is done when the suction cup device 161 is in contact with an object (such as a CPU) it creates the suction adhesion that grips the object. The suction from the vacuum line 165 may be provided by a vacuum source 164 to which it is connected. The vacuum source 164 may be any device that is capable of creating a pressure difference between the interior volume of the vacuum line 165 and ambient. For example, the vacuum source 164 may include a Venturi pump that generates a pressure drop in the vacuum line 165 based on air flow received from one or more pneumatic air supply lines 132. (The air supply lines 132 are omitted from FIGS. 1 and 2 to simplify the images, but are shown conceptually in FIG. 8). As another example, the vacuum source 164 could be an electric vacuum.

In the illustrated example, the vacuum source 164 is part of the end effector 100 and is connected to the frame 121. In other examples, the vacuum source 164 may be connected elsewhere in the end effector 100. For example, the vacuum source 164 could be connected to the frame 162, the rotating support 163, the arm connector 110, or any other place. In still other examples, the vacuum source 164 may be entirely separate from the end effector 100.

3.2. The Memory Module Gripper 120

The memory module gripper 120 will now be described in greater detail with reference to FIGS. 1-5.

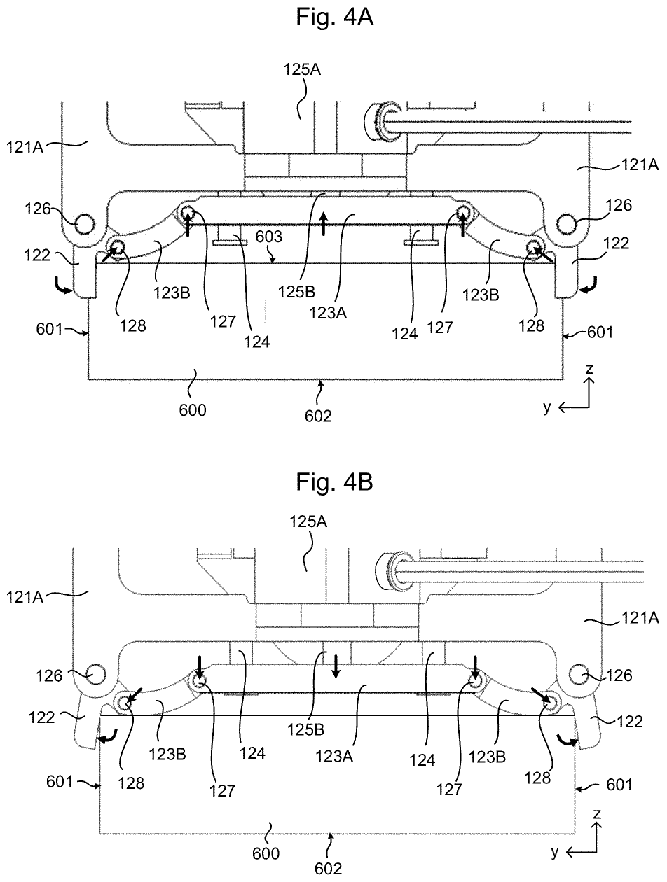

The memory module gripper 120 includes pincers 122 (see FIGS. 1-5), a mechanism that actuates the pincers 122 (described below), and a frame 121 that supports the pincers 122 (see FIGS. 1-5). The pincers 122 may be configured to grip a memory module 600. For example, the pincers 122 may be configured to rotate relative to the frame 121 so as to be capable of gripping and releasing the memory module 600. For example, FIG. 4A illustrates a configuration in which the pincers 122 are oriented so as to make contact with the edges of a memory module 600 so as to grip the memory module 600; this configuration may be referred to hereinafter as the pincers 122 being “closed”. As another example, FIG. 4B illustrates another configuration in which the pincers 122 have been rotated outward (clockwise) relative to the first configuration such that they do not grip the memory module 600; this configuration may be referred to hereinafter as the pincers 122 being “open”.

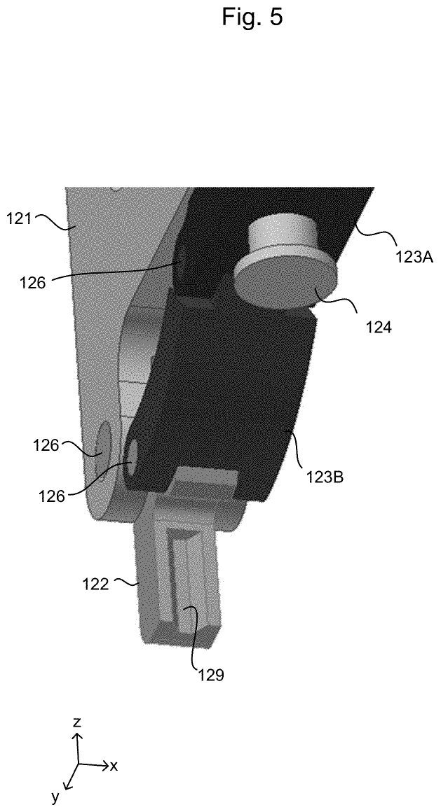

The pincers 122 may be configured to grip opposing edges of the memory module 600. Specifically, in some examples, the pincers 122 may be arranged to grip the upper corners of the two short edges 601 of the memory module 600, as illustrated in FIG. 4A. For example, the pincers 122 may be roughly L-shaped, with a gripping portion 122A that is to grip the edge of the memory module 600 and a lever portion 122B that is actuated to cause the pincer 122 to rotate about the pivot 126 (see FIG. 3). The pincers 122 may each include a groove 129 in their gripping portion 122A that is shaped to admit an edge 601 of a memory module 600 at least partially therein (see FIG. 5).

In the example illustrated in FIGS. 1-5, the mechanism that actuates the pincers 122 includes a pneumatic piston 125 (see FIGS. 1-4) and a mechanical linkage 123 (see FIGS. 1-5). The pneumatic piston 125 may include a pneumatic cylinder 125A that is affixed to the frame 121 and a piston 125B, with the piston 125B being moved upward or downward relative to the frame 121 based on air pressure supplied to the pneumatic cylinder 125A (see FIG. 3). The air pressure may be supplied, for example, by one or more pneumatic air supply lines 130 connected to connectors 125C. (The air supply lines 130 are omitted from FIGS. 1 and 2 to simplify the images, but are shown in FIGS. 3 and. 8). The mechanical linkage 123 transfers forces between the piston 125B and the pincers 122 such that the movement of the piston 125B actuates the pincers 122, causing them to rotate relative to the frame 121 about the pivots 126 (see FIGS. 3-5).

Specifically, the mechanical linkage 123 includes a first portion 123A that is slidably connected to the frame 121 by guides 124, such that the first portion 123A can slide upward or downward relative to the frame 121 (see FIGS. 3-5). The first portion 123A is also connected to the piston 125B, and thus moves upward or downward based on the movement of the piston 125B (see FIGS. 3-5). The mechanical linkage 123 also includes two second portions 123B, each being rotatably connected to the first portion 123A and rotatably connected to the lever portion 122B of one of the pincers 122 via pivots 127 and 128 (see FIGS. 3-5). When the first portion 123A is moved vertically, this is translated by the second portions 123B into diagonal movement of the pivots 128, which causes the pincers 122 to rotate relative to the frame 121 about the pivots 126 (see FIGS. 4A & B).

The actuation of the pincers 122 is illustrated in FIGS. 4A and 4B with thick arrows. The thick arrows illustrate conceptually how various parts would have moved in transitioning between the states illustrated in the two figures. The pointed end of the arrow indicates the part whose movement is being shown, while the starting end of the arrow indicates a location of that part prior to moving to its current location in that figure (the location is shown generally, and is not intended to be accurate or to scale).

For example, as illustrated by the thick arrows in FIG. 4A, the memory module gripper 120 actuates the pincers 122 from the open configuration (FIG. 4B) to the closed configuration (FIG. 4A) by causing the piston 125B to pull the first portion 123A of the mechanical linkage 123 upward, which in turn pulls the pivots 127 upward, which causes the second portions 123B to pull the pivots 128 diagonally upward/inward, which causes the pincers 122 to rotate inward about the pivots 126.

Conversely, as illustrated by the arrows in FIG. 4B, the memory module gripper 120 actuates the pincers 122 from the closed configuration (FIG. 4A) to the open configuration (FIG. 4B) by causing the piston 125B to push the first portion 123A of the mechanical linkage 123 downward, which pushes the pivots 127 downward, which causes the second portions 123B to push the pivots 128 diagonally downward/outward, which causes the pincers 122 to rotate outward about the pivots 126.

As noted above, the memory module gripper 120 includes a frame 121 that supports the mechanical linkage 123 and the pincers 122. In the example illustrated in FIGS. 1-5 the frame 121 includes a lower portion 121A and an upper portion 121B. The upper portion 121B is connected to the arm connector 110 (described in section 3.3 below), to the CPU gripper 160, and to the vacuum generator 164. The lower portion 121A extends approximately perpendicularly away from the upper portion 121B, and is connected to the pincers 122, mechanical linkage 123, and pneumatic piston 125. Thus, in the illustrated example the arm connector 110 supports the upper portion 121B, and the upper portion 121B supports the lower portion 121A and the CPU gripper 160. Although the lower portion 121A and upper portion 121B are shown as integrally connected (i.e., as a single body or piece), other examples could have the lower portion 121A and the upper potion 121B as distinct parts that are connected (e.g., via mechanical fasteners, adhesive, etc.). Furthermore, in some examples the upper portion 121B could be omitted entirely, in which case the lower portion 121A could be directly connected to the arm connector 110, to the arm of the robot, and/or to the CPU gripper 160.

In some examples, the memory module gripper 120 may be configured to grip a specific form factor of memory modules. For example, the memory module gripper 120 may be configured to grip memory modules conforming to the dual in-line memory module (“DIMM”) form factor. When it is said herein that the memory module gripper 120 is configured to grip a particular form factor, this means that its pincers 122 are arranged such that a memory module of that particular form factor is capable of being gripped by the pincers 122 and capable of being released from the pincers 122. This may include, for example, a distance between the gripping portions 122A when in a fully closed position being equal to or less than a length of the memory module along its long edges 602/603 and the distance between the gripping portions 122A when in a fully open position being greater than the length of the memory module along its long edges 602/603.

3.3. The Arm Connector 110

The end effector 100 illustrated in FIGS. 1-5 includes an arm connector 110 configured to connect the end effector 100 to the arm of a robot. The memory module gripper 120 and the CPU gripper 160 may be connected to and supported by the arm connector 110. For example, the arm connector 110 may include a first portion 111 that connects to the arm of the robot and a second portion 112 that connects to the memory module gripper 120 and CPU gripper 160. The arm connector 110 may, for example, enable the end effector 100 to be removably connected to the robot arm without requiring semi-permanent connectors such as bolts or screws.

In some examples, the arm connector 110 may be part of the end effector 100, while in other examples the arm connector 110 may be separate from the end effector 100. In some examples, the arm connector 110 may be omitted entirely, in which case the memory module gripper 120 and CPU gripper 160 may be connected directly to one another, and either or both of the grippers 120/160 may be connected directly to the robotic arm.

In the example of FIGS. 1 and 2, the memory module gripper 120 and the CPU gripper 160 are directly connected to one another, and then the memory module gripper 120 is directly connected to the arm connector 110. In other words, in the illustrated example the arm connector 110 directly supports the memory module gripper 120 and indirectly supports the CPU gripper 160. However, other examples may use other arrangements. For example, both the memory module gripper 120 and the CPU gripper 160 could be directly connected to and supported by the arm connector 110 in addition to or in lieu of being directly connected to one another. As another example, the CPU gripper 160 could be directly connected to and supported by the arm connector 110, and the memory module gripper 120 could be directly connected to and supported by the CPU gripper 160. As another example, the arm connector 110 could be an integral part of one of the grippers 120/160 rather than being a separate piece to which the grippers 120/160 are connected.

3.4 the Rotating Support 163

As noted above, in some examples of the end effector 100, the CPU gripper 160 and memory module gripper 120 rotate relative to one another. In such examples, a rotating support 163 may be included to allow this rotation. In the example illustrated in FIGS. 1 and 2, which will be the main focus of the description below, the rotating support 163 is configured to support and rotate the CPU gripper 160, but it should be understood that in other examples the rotating support 163 could be used to support and rotate the memory module gripper 120.

Specifically, in the example implementation of FIGS. 1 and 2, the rotating support 163 includes a pneumatic rotator 163A that includes an axle 163B that rotates relative to a main body of the pneumatic rotator 163A. The pneumatic rotator 163A is configured to cause its axle 163B to rotate based on air pressure received from one or more pneumatic supply lines 131. (The air supply lines 131 are omitted from FIGS. 1 and 2 to simplify the images, but are shown conceptually in FIG. 8). The axle 163B is connected to the frame 162 of the CPU gripper 160, and therefore, when the axle 163B rotates, it causes the GPU gripper 160 to rotate relative to the pneumatic rotator 163A, as illustrated by the thick double sided arrow in FIG. 1.

Furthermore, in the illustrated example, the body of the pneumatic rotator 163A is fixed relative to the memory module gripper 120 and relative to the robot arm (when the end effector 100 is installed in the robot arm). Thus, when the GPU gripper 160 is caused to rotate relative to the pneumatic rotator 163A, the GPU gripper 160 also rotates relative to the memory module gripper 120 and the robot arm. In the illustrated example, the body of the pneumatic rotator 163A is fixed relative to the memory module gripper 120 and relative to the robot arm by virtue of being directly connected to the upper portion 121B of the frame 121, which is in turn directly connected to the arm connector 110. For example, the body of the pneumatic rotator 163A may be connected to the frame 121 via a support 163C. In other examples, the body of the pneumatic rotator 163A may be directly connected to and supported by the arm connector 110 (or to the robot arm if the arm connector 110 is omitted), in addition to or in lieu of being directly connected to the frame 121.

Although the CPU gripper 160 rotates relative to the robot arm in the illustrated example, in other examples (not illustrated) the rotating support 163 may cause the memory module gripper 120 to rotate relative to the robot arm. For example, the axle 163B could be directly connected to and support the frame 121 (instead of being connected to the frame 162) and the body of the rotating support 163 could be fixed relative to CPU gripper 160 (instead of being fixed relative the memory module gripper 120). This would cause the memory module gripper 120 to rotate relative to the robot arm when the axle 163B rotates. In such an example, the body of the rotating support 163 could be fixed relative to the CPU gripper 160 by directly connecting the rotating support 163 to the CPU gripper 160 (e.g., to the frame 162) or by directly connecting both the CPU gripper 160 and the rotating support 163 to a same object, such as the arm connector 110.

Although the rotation of the rotating support 163 is provided by means of a pneumatic rotator 163A in the illustrated example, this is just one example and any other mechanism to enable rotation could be used. For example, an electricity-powered rotator (e.g., electric motor) could be used in lieu of the pneumatic rotator 163A. As another example, the rotation of the CPU gripper 160 relative to the memory module gripper 120 may be performed manually by a technician rather than automatically under power. For example, instead of including a pneumatic rotator 163A, the rotating support 163 may include a simple rotatable connector, such as a hinge or axle, which a technician can manually cause to rotate.

In some examples, instead of having the memory module gripper 120 and the CPU gripper 160 rotate relative to one another, the memory module gripper 120 and CPU gripper 160 may move translationally relative to one another between two different configurations. For example, the rotating support 163 may be replaced with a sliding support (not illustrated) that is connected to and supports either the memory module gripper 120 or the CPU gripper 160. In such an example, the sliding support enables the memory module gripper 120 or the CPU gripper 160 to move translationally relative to the other gripper and relative to the robot arm. For example, the sliding support could include a track in which a portion of the gripper 120 or 160 could be slidably connected. As another example, the sliding support could include a pneumatic piston fixed relative to the arm connector 110 and whose piston is connected to the gripper 120 or 160 and moves the gripper 120 or 160 translationally up or down. Note that, as used herein, “moves” is used to refer generically to both rotational movement and translational movement, unless indicated otherwise by the context.

### 4. Example Robotic System Using the End Effector 100

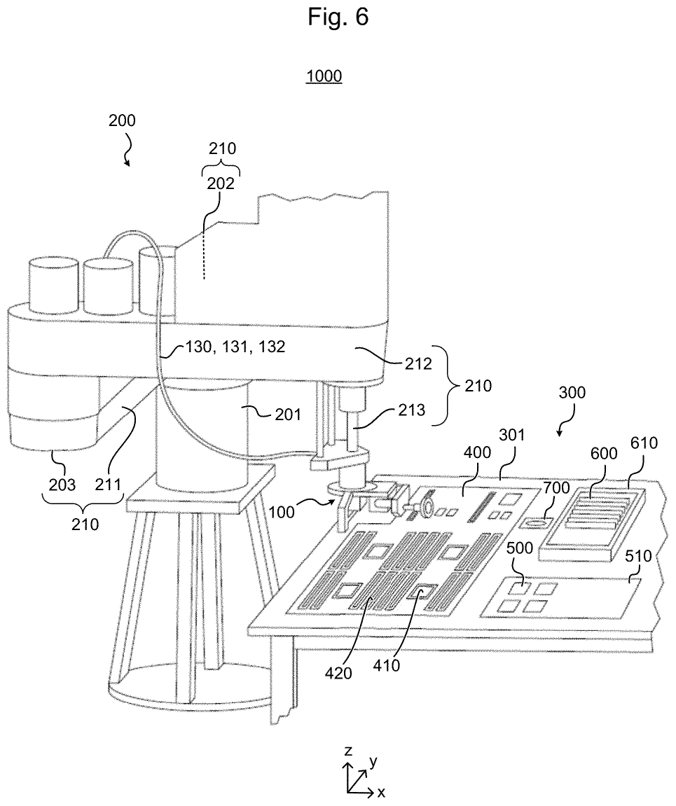

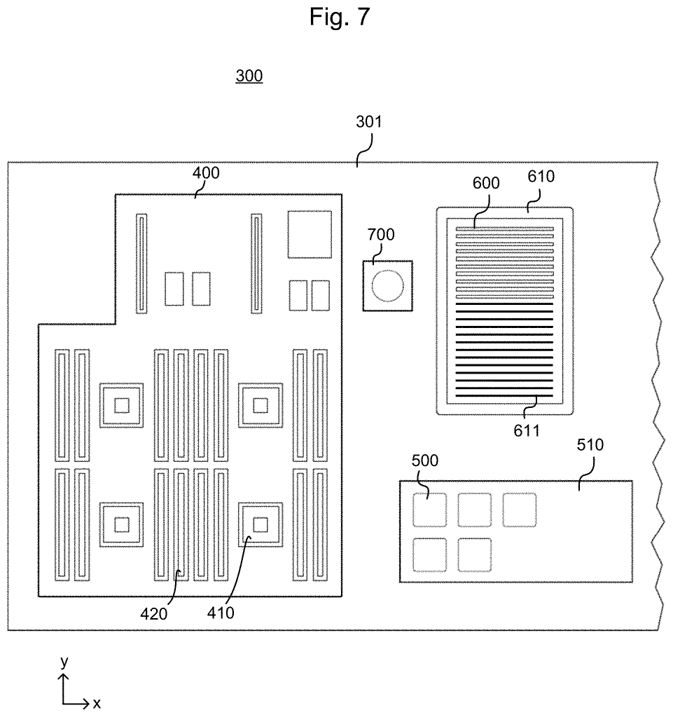

FIGS. 6-8 illustrate an example robotic system 1000 that uses the end effector 100. FIG. 6 illustrates a general setup of the system 1000, which may include a robot 200, the end effector 100, a control system 250, and a workstation 300. FIG. 7 illustrates the workstation 300 in greater detail. FIG. 8 illustrates a control or “plumbing” diagram for the system 1000.

In general, the robot 200 has an arm 210 and the end effector 100 connected to the end of the arm 210. FIG. 6 illustrates a particular example of such a robot 200, but it should be understood that any type of robot having an arm capable of moving the end effector 100 translationally in three dimensions (up/down, left/right, and forward/backward) so as to position the end effector 100 over its target payload and target installation points could be used as the robot 200 of the system 1000. In some examples, it may also be beneficial for the robot 200 to be able to rotate the end of its arm around its own longitudinal axis, so that the end effector 100 can be properly oriented relative to its target payload target installation points. Specifically, in certain examples, the robot 200 is a four-axis robot.

The particular example of a robot illustrated in FIG. 6 will now be described. The robot 200 has a base 201 and a segmented arm 210 connected to the base 201. The segmented arm 210 includes a first segment 211 that is rotatably connected to the base 201 via a joint 202 (obscured in the image), a second segment 212 that is rotatably connected to the first segment 211 via a joint 203, and an end segment 213 that is connected to the second segment 212. The end segment 213 may be translationally movable vertically (along a z-direction) relative to the second segment 212, and may be rotatable about its longitudinal axis (which is aligned with the z-direction). The end effector 100 is attached to the end of the arm 210, specifically to the bottom of the end segment 213. Thus, the end effector 100 is moved horizontally (in the ±x and/or ±y directions) via rotation of the joints 202 and 203, and is moved vertically (in the ±z directions) by extending or retracting the end segment 213 relative to the second segment 212.

The workstation 300 may include a PCB 400, a CPU tray 510, and a memory tray 610, all of which may be supported by one or more support surfaces 301. The workstation 300 may also include a sensor 700. The workstation 300 may also include a heatsink tray (not illustrated).

The CPU tray 510 may hold processors 500 and/or heatsinks 520 with a top thereof facing upward (+z direction). In some examples, only processors 500 are to be installed by the robot 200, in which case the CPU tray 510 may contain just processors 500. In some examples, processors 500 and heatsinks 520 are both to be installed by the robot 200, and the processors 500 and heatsinks 520 have already been connected together into an assembly, in which case the CPU tray 510 may hold such assemblies. In some examples, processors 500 and heatsinks 520 are both to be installed by the robot 200, but they are not yet connected to one another; in such examples, the processors 500 may be held in the CPU tray 510 and the heatsinks 520 may also be held in the CPU tray 510 or may be held in a separate heatsink tray (not illustrated).

The robot 200 may grip such processors 500 and/or heatsinks 520 by positioning the end effector 100 above the target payload with the CPU gripper 160 in its gripping configuration, lowering the end segment 213 to a first pre-specified height at which the CPU gripper 160 is expected to contact the target payload, and causing the CPU gripper 160 to grip the target payload by suction adhesion.

The robot 200 may then move the CPU 500 and/or heatsink 520 to a location above a CPU socket 410 in the PCB 400, and lower the robot arm to a second pre-specified height at which the processor 500 is expected to be fully seated in the socket 410 and/or the heatsink 520 is seated on the processor 500. Upon the robot arm 213 reaching the second pre-specified height, the suction of the CPU gripper 160 may be ceased, thus releasing the processor 500 and/or heatsink 520. If the processor 500 and/or the heatsink 520 are fully seated before the robot arm 213 reaches the second pre-specified height (e.g., if the CPU socket 410 is higher than expected), then the suction cup portion 161A of the CPU gripper 160 elastically deforms rather than rigidly pushing against the processor 500 and/or heatsink. Thus, the force applied to the processor is the fairly moderate elastic restoring force resulting from the deformation, rather than the full force of the robot arm 213. Thus, damage to the components is avoided.

The memory tray 610 may hold memory modules 600 such that the short edges 601 thereof are vertical (+z direction) and long edges (602 and 603) thereof are horizontal, with a top edge 603 of the memory module 600 facing upward and the bottom edge 602 facing downward (the bottom edge 602 is the edge that is to be plugged into the memory module socket 420, and thus includes electrical connections such as gold fingers/pins). For example, the memory tray 610 may hold the memory modules 600 in slots 611. In some examples, the memory modules 600 may be bare, while in other examples the memory modules 600 may have additional components already installed thereon, such as memory heat spreaders or memory heat sinks. In examples in which the memory modules 600 have other components installed thereon, references herein to gripping the memory modules 600 would include gripping the memory modules 600 via the components—for example, if the memory modules 600 have heat spreaders installed thereon, the pincers 122 may grip the memory module 600 indirectly by making direct contact with the heat spreaders.

The robot 200 may grip such memory modules 600 from the memory tray 610 by positioning the end effector 100 above the target memory module 600 with the CPU gripper 160 moved (e.g., rotated) out of the way of the memory module gripper 120, lowering the end segment 213 to a third pre-specified height at which the memory module gripper 120 is in position to grip the target memory module 600, and actuating the pneumatic piston 125 to cause the memory module gripper 120 to close its pincers 122 to grip the target memory module 600.

The robot 200 may then move the memory module 600 to a location over a memory module socket 420 in the PCB 400, and lower the end segment 213 to a fourth pre-specified height at which the memory module 600 is expected to be partially seated in the socket 420. Upon the end segment 213 reaching the fourth pre-specified height, the pneumatic piston 125 is actuated to cause the pincers 122 to rotate to an open configuration and release the memory module 600. At this stage, the memory module is only partially seated in the memory module socket 420. With the pincers 122 in the open configuration, as illustrated in FIG. 4B, the end segment 213 may be moved further downward to a fifth pre-specified height at which the memory module 600 is expected to be fully seated in the socket 420. This movement causes the mechanical linkage 123 (specifically, the portions 123B) to press downward against the memory module 600, and thereby causes the memory module 600 to become fully seated within the socket 420. If the memory module 600 is fully seated (e.g., reaches the bottom of the socket 420) before the end segment 213 stops moving downward, the memory module 600 will push upward against the mechanical linkage 123, which in turn will push upward against the piston 125B, which results in the air in the pneumatic cylinder 125A compressing (i.e., the internal pressure of the cylinder 125A increases). This interaction results in a moderate force being applied to the memory module 600 that is proportional to the force needed to compress the air, rather than the full force of the end segment 213. Thus, damage to the memory module 600 is avoided.

As noted above, in the workstation 300 the memory modules 600 and the processors 500 and/or heatsinks 520 are all held in such a way as to be gripped from the same direction. That is, each object is arranged to be gripped from directly above it. In addition, the PCB 400 is arranged to have the components installed from that same direction (i.e., from above). This allows a relatively simple setup of the workstation 300, in which the CPU trays 510, memory trays 600, and PCB 400 may all be located on simple horizontal surfaces 301 (or on the same horizontal surface 301).

The control system 250 that controls the robot 200 includes a controller 250 and an end-effector actuation system 256 (see FIG. 8). The controller 250 includes control logic 255 that is configured to control the movements of the robot arm 210 and to control actuation of the end effector 100 via the end-effector actuation system 256. The control logic 255 may control the movements of the robot arm 210 by sending arm control signals to the robot 200. The control logic 255 may control actuation of the end effector 100 by sending actuation control signals to the end-effector actuation system 256.

The control logic 255 may include any combination of hardware and machine-executable instructions that is configured to control the movements of the robot arm 210 and the operations of the end effector 100. For example, the control logic 255 could include a general-purpose processor and controller software (machine readable/executable instructions) stored on a non-transitory machine readable medium that, when executed by the processor, causes the processor to send control signals to the robot 200 and/or other portions of the system 1000. The control logic 255 could also include dedicated hardware, such as ASICs, CPLDs, FPGAs, etc. The control logic 255 may be part of the robot 200, or may be provided separately from the robot 200 and may communicate control signals to the robot 200 and other portions of the system 1000 via electrical, optical, or wireless connections (signals to and from the control logic 255 are indicated by single solid lines in FIG. 8). The control logic 255 may receive information from sensors 700 and/or 750, and may base its control of the robot 200 on this information.

The end-effector actuation system 256 may include a pneumatic air supply 267 and solenoid valves 258. As illustrated in FIG. 8, the air supply 267 supplies air flow (air pressure) to the solenoid valves 258 (airflow is indicated by double solid lines in FIG. 8). The solenoid valves 258A-C are connected to air supply lines 130, 131, and 132, respectively, such that each solenoid valves 258 supplies air pressure from the air supply 267 to its respective air supply line 131, 132, 133 when (and only when) the valve 258 is open. The solenoid valves 258 are controlled to open and close by control signals 259 received from the control logic 255.

For example, to actuate the pneumatic piston 125 the control logic 255 may control the opening/closing of the solenoid valves 258A. For example, one solenoid valve 258A may be opened to extend the piston 125B downward, and another solenoid valve 258A may be opened to retract the piston 1256 upward. As another example, to actuate the pneumatic rotator 163A the control logic 255 may control the opening/closing of the solenoid valves 2586. For example, one solenoid valve 258B may be opened to rotate the axle 163B in one direction, and another solenoid valve 258B may be opened to rotate the axle 163B in another direction. As another example, to actuate the suction cup device 161 the control logic 255 may control the opening/closing of the solenoid valves 258C. For example, to cause the vacuum source 164 to begin suction, one of the solenoid valves 258C may be opened.

Although the end-effector actuation system 256 that is illustrated in FIG. 8 includes pneumatic elements to match pneumatic elements of the end effector 100, the end-effector actuation system 256 may also include other mechanisms to actuate the end effector 100. For example, if the end effector 100 includes electrically actuated elements, such as an electric piston in lieu of the pneumatic piston 125 or an electric rotator in lieu of the pneumatic rotator 163A or an electric vacuum in lieu of a Venturi vacuum, then an electrical power source could be provided in addition to or in lieu of the air supply 257, electrical switches could be provided in lieu of or in addition to the solenoid valves 258, and electrical supply lines could be provided in lieu of or in addition to air supply lines 130, 131, 132.

The sensor 700 may be used by the control logic 255 to ensure that the robot 200 has successfully gripped its target payload, and if so to identify an orientation of the payload. For example, the robot 200 may move the end effector 100 over the sensor 700 after attempting to grip a payload so that the sensor 700 can sense the presence and/or orientation of the payload. The sensor 700 can be any sensor that is capable of detecting whether a payload has been gripped and/or an orientation of the payload.

For example, the sensor 700 may include an optical sensor that detects the presence and/or orientation of the payload by analyzing an image sensed by the sensor 700. For example, the image sensed by the sensor 700 could be compared to a database of training images to find a closest match. For example, the processors 500, heatsinks 520, and/or memory modules 600 may be given distinguishing visual marks, such as symbols, notches, etc., to allow the sensory 700 to quickly identify their presence and orientation. For example, some memory modules 600 may already include alignment notches (also called keys) for other purposes, and the sensor 700 may detect the presence and/or orientation of a memory module 600 by detecting such notches. As another example, the image sensed by the sensor 700 could be analyzed for encoded information, such as a barcode (e.g., linear barcode, 2-D matrix barcode, etc.), which may be included on the various payloads.

As another example, the sensor 700 could be a near-field-communication (NFC) sensor that detects the presence of an NFC chip on the processors 500, heatsinks 520, and/or memory modules 600.

In some examples, the sensor 700 itself processes/analyzes the raw data it senses to explicitly detect the presence and/or orientation of the payload, and the sensor 700 reports the detection result to the control logic 255. In other examples, the sensor 700 may provide un-processed or lightly processed data (such as an image) to the control logic 255, and the control logic 255 may perform additional processing or analysis on the data to detect the presence and/or orientation of the payload. Other examples may include something between these two extremes, in which the sensor 700 and control logic 255 may both perform some level of processing/analysis to detect the payload and its orientation. For simplicity, all of these possibilities will be described herein and in the appended claims as the sensor “detecting” the payload/orientation. In other words, as used herein, the sensor “detecting” the presence and/or orientation of payload is meant to broadly include either the sensor explicitly identifying the presence/orientation payload from its sensed data or the sensor providing its sensed data to another entity (such as the control logic 255) from which the other entity identifies the presence/orientation of the payload.

In some examples, the robot 200 may also include a position guidance system (not illustrated) that aids the control logic 255 in positioning the robot arm 213 in the x-y directions. Specifically, the position guidance system may help ensure that the payload gripped by the end effector 100 is positioned correctly over its target installation location (e.g., socket 410 or 420). The position guidance system may include one or more sensors 750 (such as optical sensors) that provide information to the control logic 255 that indicates a position of the end effector 100 relative to a target installation location. The information provided by the position guidance system may explicitly indicate the relative location (e.g., via a vector representation), or may implicitly indicate the position by providing information (such as an image) from which the control logic 255 can determine the location. Based on this location information, the control logic 255 may then determine how it needs to move the robot arm 213 to align the payload over its target installation location.

The position guidance system may allow for some tolerance of variations in the x-y locations of CPU sockets 410 and memory module sockets 420 within the PCB 400. Such tolerance in x-y location of the sockets can reduce costs because ensuring a high precision in socket placement may require more expensive manufacturing processes. This may also allow for more tolerance in the location of the PCB 400 relative to the robot 200, which may result in a simpler and less expensive workstation 300 setup.

### 5. Example Method of Using the End Effector 100

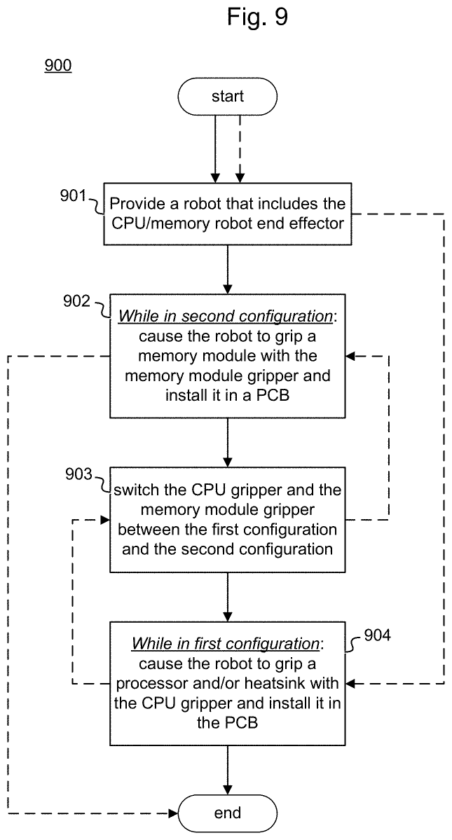

FIG. 9 illustrates and example method 900. The steps of the method may be performed in either of two different sequences, which are illustrated in FIG. 9. In particular, solid-line connectors illustrate a first sequence of steps for the method 900, while dashed-line connectors illustrate a second sequence of steps for the method 900. The steps will be described below in the order of the first sequence (sold-line connectors).

In block 901, a robot is provided that includes one of the example robot end effectors described herein, such as the robot end effector 100.

In block 902, while in the second configuration in which the memory module gripper 120 is positioned to grip memory modules 600 and the CPU gripper 160 is not positioned to grip, the robot is caused to: grip a memory module 600 with the memory module gripper 120, install the memory module 600 in a memory module socket 420 of a circuit board 400, and release the memory module 600 from the memory module gripper 120. In some examples, installing the memory module 600 may include partially seating the memory module 600 in the socket 420, then releasing the module 600, then fully seating the memory module 600, as described in section 4 above. In some examples, installing the memory module 600 may include passing the robot arm 213 over the sensor 700 to verify that the memory module 600 has been properly griped and/or to check an orientation of the memory module 600. This block may be repeated multiple times before moving on to the next block, if desired. For example, if the PCA being assembled from the PCB 400 is slated to have eight memory modules 600, then block 902 may be performed eight times to install eight memory modules 600 in the PCB 400.

In block 903, the CPU gripper 160 and the memory module gripper 120 are switched between the first configuration and the second configuration between installing the memory module 600 and installing the CPU 500 and/or heatsink 520. In some examples, switching between the first and second configurations includes rotating the CPU gripper 160 relative to the memory module gripper 120.

In block 904, while in the first configuration in which the CPU gripper 160 is positioned to grip processors 500 and/or heatsinks 520, the robot is caused to: grip a processor 500 and/or heatsink 520 with the CPU gripper 160, install the processor 500 and/or heatsink 520 in a CPU socket 410 of a circuit board 400, and release the processor 500 and/or heatsink 520 from the CPU gripper 160. In some examples, installing the processor 500 and/or heatsink 520 may include passing the robot arm 213 over the sensor 700 to verify that the processor 500 and/or heatsink 520 has been properly griped and/or to check an orientation of the processor 500 and/or heatsink 520. This block may be repeated multiple times before moving on to the next block, if desired. For example, if the PCA being assembled from the PCB 400 is slated to have four processors 500 each with a heat sink 520, then block 902 may be performed four or eight times (depending on whether each processor 500 and its heat sink 520 are installed together as a single assembly or separately).

Gripping Axis:

As used herein, the “gripping axis” of a gripper corresponds to a line that passes through the gripper and its payload when the payload is positioned so as to be grippable by the gripper. In other words, the gripping axis is aligned with the direction in which the gripper is pointing. So, for example, the gripping axis of the memory module gripper 120 in FIGS. 1-5 is parallel to the z axis, since a memory module 600 would need to be positioned directly below the memory module gripper 120 in order to be gripped by it.

Processor.

As used herein, “processor” is used generically to include any physical processing device, such as a central processing unit (CPU), graphical processing unit (GPU), system-on-chip (SoC), application-specific-integrated-circuit (ASIC), field-programmable-gate-array (FPGA), complex-programmable-logic-device (CPLD), digital signal processor, baseboard management controller (BMC), and the like.

Provide:

As used herein, to “provide” an item means to have possession of and/or control over the item. This may include, for example, forming (or assembling) some or all of the item from its constituent materials and/or, obtaining possession of and/or control over an already-formed item.

A number.

Throughout this disclosure and in the appended claims, occasionally reference may be made to “a number” of items. Such references to “a number” mean any integer greater than or equal to one. When “a number” is used in this way, the word describing the item(s) may be written in pluralized form for grammatical consistency, but this does not necessarily mean that multiple items are being referred to. Thus, for example, a phrase such as “a number of active optical devices, wherein the active optical devices . . . ” could encompass both one active optical device and multiple active optical devices, notwithstanding the use of the pluralized form.

The fact that the phrase “a number” may be used in referring to some items should not be interpreted to mean that omission of the phrase “a number” when referring to another item means that the item is necessarily singular or necessarily plural.

In particular, when items are referred to using the articles “a”, “an”, and “the” without any explicit indication of singularity or multiplicity, this should be understood to mean that there is “at least one” of the item, unless explicitly stated otherwise. When these articles are used in this way, the word describing the item(s) may be written in singular form and subsequent references to the item may include the definite pronoun “the” for grammatical consistency, but this does not necessarily mean that only one item is being referred to. Thus, for example, a phrase such as “an optical socket, wherein the optical socket . . . ” could encompass both one optical socket and multiple optical sockets, notwithstanding the use of the singular form and the definite pronoun.

And/or.

Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Various example processes were described above, with reference to various example flow charts. In the description and in the illustrated flow charts, operations are set forth in a particular order for ease of description. However, it should be understood that some or all of the operations could be performed in different orders than those described and that some or all of the operations could be performed concurrently (i.e., in parallel).

While the above disclosure has been shown and described with reference to the foregoing examples, it should be understood that other forms, details, and implementations may be made without departing from the spirit and scope of this disclosure.

What is claimed is:

1. A robot end effector, comprising:
a memory module gripper that is configured to selectively grip a memory module; and
a CPU gripper that is configured to selectively grip a processor and/or a heatsink,
wherein the CPU gripper is attached to the memory module gripper such that they are movable relative to the one another between a first configuration and a second configuration.

2. The robot end effector of claim 1,
wherein the CPU gripper and the memory module gripper are rotatable relative to the one another between the first configuration and the second configuration.

3. The robot end effector of claim 2,
wherein, in the first configuration, a gripping axis of the CPU gripper and a gripping axis of the memory module gripper are substantially parallel, and
in the second configuration, the gripping axis of the CPU gripper and the gripping axis of the memory module gripper are substantially perpendicular.

4. The robot end effector of claim 1,
wherein the memory module gripper includes a frame, a pneumatic piston connected to the frame, pincers rotatably connected to the frame, and a mechanical linkage that converts between translational movement of a piston of the pneumatic piston and rotation of the pincers,
the pincers are configured to grip opposing edges of a memory module when rotated to a first orientation and to release the memory module when rotated to a second orientation.

5. The robot end effector of claim 1,
wherein the CPU gripper includes a vacuum suction cup that is to selectively grip the processor and/or the heatsink.

6. The robot end effector of claim 5, further comprising:
a rotating support that rotates the CPU gripper relative to the memory module gripper.

7. The robot end effector of claim 1,
wherein the rotating support includes a pneumatic rotator that is fixed relative to the memory module gripper, an axle of the pneumatic rotator is connected to the CPU gripper.

8. The robot end effector of claim 1,
wherein the memory module gripper has compliancy for the memory module resisting being pushed by the memory module gripper along the gripping axis of the memory module gripper.

9. The robot end effector of claim 1,
wherein the CPU gripper has compliancy for the processor and/or heatsink resisting being pushed by the CPU gripper along the gripping axis of the CPU gripper.

10. A system comprising:
a robot that includes the robot end effector of claim 1.

11. The system of claim 10, comprising:
a sensor configured to detect
whether a payload has been gripped by the robot end effector, and/or
an orientation of a payload that has been gripped by the robot end effector.

12. The system of claim 11,
wherein the sensor is an optical sensor configured to detect an alignment notch of a memory module gripped by the robot end effector.

13. The system of claim 10, comprising:
wherein the robot is a 4-axis robot.

14. The system of claim 10, further comprising:
a control system configured to cause the robot to:
with the CPU gripper and the memory module gripper in the second configuration, use the memory module gripper to grip a memory module from a memory module supply station and install the memory module in a circuit board;
with the CPU gripper and the memory module gripper in the first configuration, use the CPU gripper to grip a processor and/or a heatsink from a CPU supply station and install the processor in the circuit board; and
switch between the first configuration and the second configuration between installing the memory module and installing the processor and/or heatsink.

15. The system of claim 10, further comprising:
a control system configured to cause the robot to install a memory module in a circuit board by:
using the memory module gripper to grip the memory module,
positioning the memory module over a socket of the circuit board,
partially seating the memory module in the socket by moving the robot end effector to a first specified height,
releasing the memory module from the memory module gripper, and
completing seating of the memory module by applying force from the memory module gripper to the memory module by moving the robot end effector to a second specified height.

16. A method, comprising:
providing a robot that includes the robot end effector of claim 1;
causing the robot to, with the CPU gripper and the memory module gripper in the second configuration: grip a memory module with the memory module gripper and install the memory module in a memory module socket of a circuit board;
causing the robot to, with the CPU gripper and the memory module gripper in the first configuration: grip a processor and/or a heatsink with the CPU gripper and install the processor and/or heatsink in a CPU socket of the circuit board; and
switching the CPU gripper and the memory module gripper between the first configuration and the second configuration between installing the memory module and installing the processor or heatsink.

17. The method of claim 16,
wherein switching the CPU gripper and the memory module gripper between the first configuration and the second configuration includes rotating the CPU gripper relative to the memory module gripper.

18. The method of claim 16, comprising:
as part of installing the memory module in the memory module socket, causing the robot to:
partially seat the memory module in the memory module socket by moving the robot end effector to a first specified height, and then
release the memory module, and then
finish seating of the memory module by applying force from the memory module gripper to the memory module by moving the robot end effector to a second specified height.
